(19) United States
(12) Patent Application Publication
(10) Pub. No.: US 2016/0093754 A1
(43) Pub. Date: Mar. 31, 2016

(54) SOLAR CELL

(71) Applicant: Panasonic Intellectual Property Management Co., Ltd., Osaka (JP)

(72) Inventors: Tsuyoshi TAKAHAMA, Osaka (JP); Naofumi HAYASHI, Osaka (JP); Taiki HASHIGUCHI, Osaka (JP); Akimichi MAEKAWA, Osaka (JP)

(21) Appl. No.: 14/863,579

(22) Filed: Sep. 24, 2015

(30) Foreign Application Priority Data
Sep. 25, 2014 (JP) 2014-194836

(51) Int. Cl. H01L 31/0224

(52) U.S. Cl. CPC H01L 31/022441

(57) ABSTRACT

A solar cell includes: a semiconductor substrate of one conductivity type; a first semiconductor layer of the one conductivity type on the semiconductor substrate; a second semiconductor layer of the other conductivity type on the semiconductor substrate; an insulation layer between the first and second semiconductor layers in an area where the first and second semiconductor layers layer overlap each other; a first region where the first semiconductor layer is joined to the semiconductor substrate; a second region where the second semiconductor layer is joined to the semiconductor substrate; and a third region, which is a part of the first region, where the insulation layer is provided. The first region includes first finger sections and a first busbar section. The second region includes second finger sections and a second busbar section. At least a part of the first busbar section is provided in the third region.

### CROSS REFERENCE TO RELATED APPLICATIONS

This application claims priority based on 35 USC 119 from prior Japanese Patent Application No. 2014-194836 filed on Sep. 25, 2014, entitled “SOLAR CELL”, the entire contents of which are incorporated herein by reference.

### BACKGROUND OF THE INVENTION

1. Field of the Invention

This disclosure relates to a solar cell.

2. Description of the Related Art

As a solar cell with high power generation efficiency, a so-called back contact solar cell has been proposed in which a p-type region and an n-type region are formed on the back surface side of the solar cell (e.g. International Publication No. WO2012/132655). The back contact solar cell can enhance the light reception efficiency since no electrodes need to be provided on the light receiving surface side.

As an example of the structure of the back contact solar cell, there is a structure in which the p-type region and the n-type region each include finger sections and a busbar section to which the finger sections are connected, and the finger sections of the p-type region and the finger sections of the n-type region interdigitate each other.

### SUMMARY OF THE INVENTION

The solar cell with the above structure is, however, desired to achieve a further improvement in photoelectric conversion efficiency.

An object of an embodiment of the invention is to provide aback contact solar cell with improved photoelectric conversion efficiency.

An aspect of the invention is a solar cell that includes: a semiconductor substrate of one conductivity type including a main surface; a first semiconductor layer of the one conductivity type formed on the main surface of the semiconductor substrate; a second semiconductor layer of the other conductivity type formed on the main surface of the semiconductor substrate; and an insulation layer provided between the first semiconductor layer and the second semiconductor layer in an area where the first semiconductor layer and the second semiconductor layer overlap each other. The solar cell includes a first region where the first semiconductor layer is joined to the semiconductor substrate, a second region where the second semiconductor layer is joined to the semiconductor substrate, and a third region, which is apart of the first region, where the insulation layer is provided. The first region includes first finger sections which extend in a predetermined direction and a first busbar section to which one end of each of the first finger sections is connected. The second region includes second finger sections which extend in the predetermined direction and a second busbar section to which one end of each of the second finger sections is connected. The first finger sections and the second finger sections interdigitate each other. At least a part of the first busbar section is provided in the third region.

According to the aspect of the invention, the photoelectric conversion efficiency of the back contact solar cell can be improved.

### BRIEF DESCRIPTION OF THE DRAWINGS

FIG. 1 is a schematic plan view illustrating a solar cell according to a first embodiment.

FIG. 2A is an enlarged schematic cross-sectional view illustrating a part of a cross section along line I-I in FIG. 1.

FIG. 2B is a schematic cross-sectional view along line II-II in FIG. 1, and FIG. 2C is a schematic cross-sectional view along line III-III in FIG. 1.

FIG. 3 is a view illustrating the arrangement of a first region in the first embodiment.

FIG. 4 is a view illustrating the arrangement of a second region in the first embodiment.

FIG. 5 is a view illustrating the arrangement of a third region in the first embodiment.

FIG. 6 is a schematic cross-sectional view for explaining a step for manufacturing the solar cell in the first embodiment.

FIGS. 7A to 7C are views for explaining a step for manufacturing the solar cell in the first embodiment, and FIG. 7A is an enlarged schematic cross-sectional view illustrating a part of a cross section along line I-I in FIG. 1, FIG. 7B is a schematic cross-sectional view illustrating a part of a cross section along line II-II in FIG. 1, and FIG. 7C is a schematic cross-sectional view illustrating a part of a cross section along line III-III in FIG. 1.

FIGS. 8A to 8C are views for explaining a step for manufacturing the solar cell in the first embodiment, and FIG. 8A is an enlarged schematic cross-sectional view illustrating the part of the cross section along line I-I in FIG. 1, FIG. 8B is a schematic cross-sectional view illustrating the part of the cross section along line II-II in FIG. 1, and FIG. 8C is a schematic cross-sectional view illustrating the part of the cross section taken along line III-III in FIG. 1.

FIGS. 9A to 9C are views for explaining a step for manufacturing the solar cell in the first embodiment, and FIG. 9A is an enlarged schematic cross-sectional view illustrating the part of the cross section along line I-I in FIG. 1, FIG. 9B is a schematic cross-sectional view illustrating the part the cross section along line II-II in FIG. 1, and FIG. 9C is a schematic cross-sectional view illustrating the part of the cross section along line III-III in FIG. 1.

FIGS. 10A to 10C are views for explaining a step for manufacturing the solar cell in the first embodiment, and FIG. 10A is an enlarged schematic cross-sectional view illustrating the part of the cross section along line I-I in FIG. 1, FIG. 10B is a schematic cross-sectional view illustrating the part of the cross section along line II-II in FIG. 1, and FIG. 10C is a schematic cross-sectional view illustrating the part of the cross section along line III-III in FIG. 1.

FIGS. 11A to 11C are views for explaining a step for manufacturing the solar cell in the first embodiment, and FIG. 11A is an enlarged schematic cross-sectional view illustrating the part of the cross section along line I-I in FIG. 1, FIG. 11B is a schematic cross-sectional view illustrating the part of the cross section along line II-II in FIG. 1, and FIG. 11C is a schematic cross-sectional view illustrating the part of the cross section along line in FIG. 1.

FIGS. 12A to 12C are views for explaining a step for manufacturing the solar cell in the first embodiment, and FIG. 12A is an enlarged schematic cross-sectional view illustrating the part of the cross section along line I-I in FIG. 1, FIG. 12B is a schematic cross-sectional view illustrating the part of the cross section along line II-II in FIG. 1, and FIG. 12C is a schematic cross-sectional view illustrating the part of the cross section along line in FIG. 1.

FIGS. 13A to 13C are views for explaining a step for manufacturing the solar cell in the first embodiment, and FIG. 13A is an enlarged schematic cross-sectional view illustrating the part of the cross section along line I-I in FIG. 1, FIG. 13B is a schematic cross-sectional view illustrating the part of the cross section along line II-II in FIG. 1, and FIG. 13C is a schematic cross-sectional view illustrating the part of the cross section along line in FIG. 1.

FIGS. 14A to 14C are views for explaining a step for manufacturing the solar cell in the first embodiment, and FIG. 14A is an enlarged schematic cross-sectional view illustrating the part of the cross section taken along line I-I in FIG. 1, FIG. 14B is a schematic cross-sectional view illustrating the part of the cross section along line II-II in FIG. 1, and FIG. 14C is a schematic cross-sectional view illustrating the part of the cross section along line in FIG. 1.

FIG. 15 is a view illustrating the arrangement of a third region in a solar cell of a comparison example.

FIGS. 16A to 16C are views illustrating the structure of the solar cell of the comparison example, and A is an enlarged schematic cross-sectional view illustrating a cross section of a part of the comparison example structure, which corresponds to the part taken along line I-I in FIG. 1, FIG. 16B is a schematic cross-sectional view illustrating a cross section of a part of the comparison example structure, which corresponds to the part taken along line II-II in FIG. 1, and FIG. 16C is a schematic cross-sectional view illustrating a cross section of a part of the comparison example structure, which corresponds to the part taken along line in FIG. 1.

### DESCRIPTION OF THE PREFERRED EMBODIMENTS

A preferred embodiment is described below. It is to be noted that the following embodiment is a mere example, and the invention is not limited to the following embodiment. Moreover, in the drawings, members with substantially the same function may be referred to by the same reference numeral.

### First Embodiment

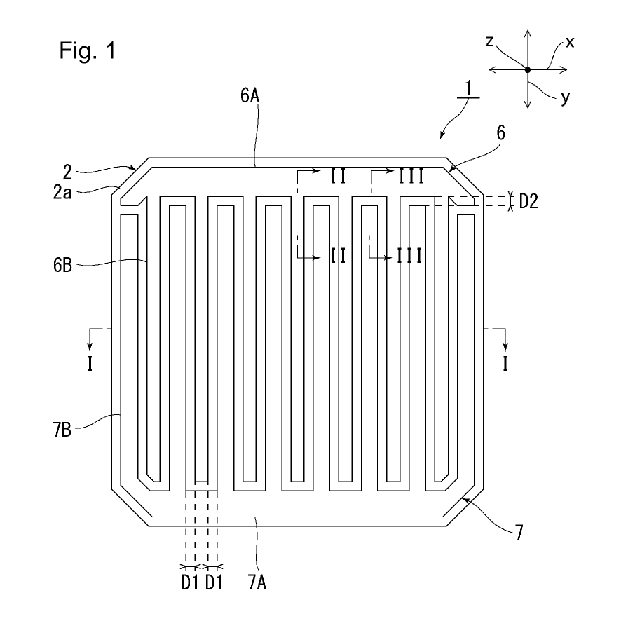

FIG. 1 is a schematic plan view of a solar cell in a first embodiment.

Solar cell 1 includes semiconductor substrate 2. Semiconductor substrate 2 includes a main surface (not illustrated) as the light receiving surface and main surface 2a as the back surface. Carriers are produced when the light receiving surface receives light. Here, the carriers are holes and electrons produced as a result of absorption of light by semiconductor substrate 2. The holes are collected by p-side electrode 7 while the electrons are collected by n-side electrode 6. Details of p-side electrode 7 and n-side electrode 6 are described later.

Semiconductor substrate 2 is formed by a crystalline semiconductor substrate of a conductivity type of either n type or p type. Specific examples of the crystalline semiconductor substrate may include crystalline silicon substrates such as a monocrystalline silicon substrate and a polycrystalline silicon substrate. Note that semiconductor substrate 2 can also be formed by other types of semiconductor substrate than the above crystalline semiconductor substrates. In the following, this embodiment describes an example where semiconductor substrate 2 is formed by a crystalline silicon substrate of n type as one conductivity type.

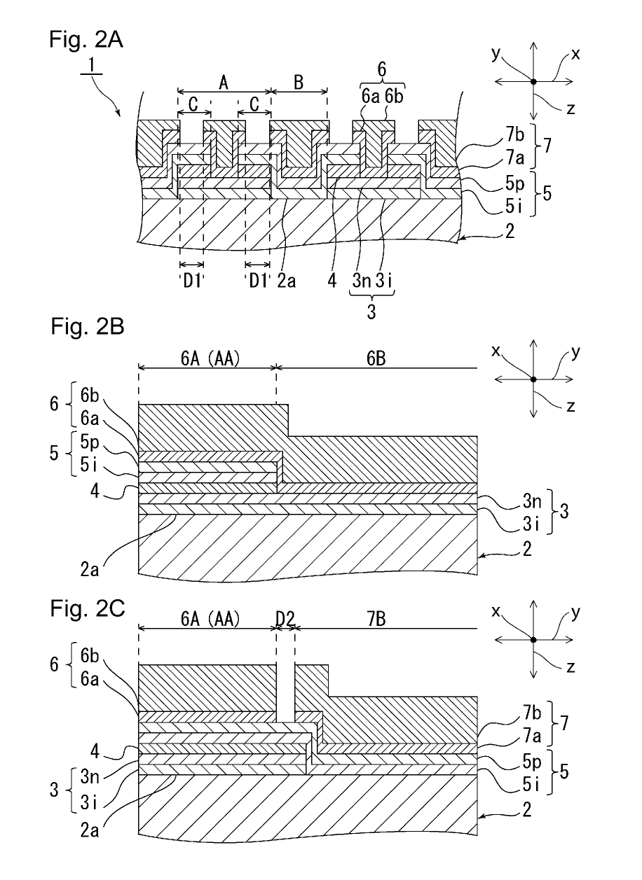

FIG. 2A is an enlarged schematic cross-sectional view illustrating a part of a cross section along line I-I illustrated in

FIG. 1. FIG. 2B is a schematic cross-sectional view along line II-II illustrated in FIG. 1. FIG. 2C is a schematic cross-sectional view along line III-III illustrated in FIG. 1.

First semiconductor layer 3 of the one conductivity type and second semiconductor layer 5 of the other conductivity type are formed on main surface 2a of semiconductor substrate 2. In this embodiment, the first semiconductor layer is of n type while the second semiconductor layer is of p type. Here, a region where first semiconductor layer 3 is joined to semiconductor substrate 2 is referred to as first region A, and a region where second semiconductor layer 5 is joined to semiconductor substrate 2 is referred to as second region B. First region A and second region B are described later in detail.

First semiconductor layer 3 includes a stacked structure including i-type amorphous semiconductor film 3i, as a first intrinsic semiconductor film, formed on main surface 2a of semiconductor substrate 2, and n-type amorphous semiconductor film 3n, as a first semiconductor film, formed on i-type amorphous semiconductor film 3i. I-type amorphous semiconductor film 3i is made of amorphous silicon containing hydrogen. N-type amorphous semiconductor film 3n is an amorphous semiconductor film of n type in which an n-type dopant is added. In this embodiment, n-type amorphous semiconductor film 3n is made of n-type amorphous silicon containing hydrogen.

Insulation layer 4 is formed on n-type amorphous semiconductor film 3n. Center sections of n-type amorphous semiconductor film 3n in an x direction, as a widthwise direction, are not covered with insulation layer 4. In this embodiment, insulation layer 4 is made of silicon nitride. Note that the material of insulation layer 4 is not particularly limited. For example, insulation layer 4 maybe made of silicon oxide, silicon oxynitride, or the like. Also, insulation layer 4 preferably contains hydrogen.

Second semiconductor layer 5 is formed on semiconductor substrate 2 in the second region and on insulation layer 4. In other words, insulation layer 4 is formed between first semiconductor layer 3 and second semiconductor layer 5 in areas where first semiconductor layer 3 and second semiconductor layer 5 overlap each other.

Second semiconductor layer 5 includes a stacked structure including i-type amorphous semiconductor film 5i, as a second intrinsic semiconductor film, and p-type amorphous semiconductor film 5p, as a second semiconductor film, formed on i-type amorphous semiconductor film 5i. I-type amorphous semiconductor film 5i is made of amorphous silicon containing hydrogen. P-type amorphous semiconductor film 5p is an amorphous semiconductor film of p type in which a p-type dopant is added. In this embodiment, p-type amorphous semiconductor film 5p is made of p-type amorphous silicon containing hydrogen.

In this embodiment, i-type amorphous semiconductor film 5i, which has such a thickness that it does not practically contribute to the power generation, is provided between crystalline semiconductor substrate 2 and p-type amorphous semiconductor film 5p. By providing i-type amorphous semiconductor film 5i between n-type semiconductor substrate 2 and p-type amorphous semiconductor film 5p as in this embodiment, it is possible to suppress recombination of minority carriers at the joint interface between semiconductor substrate 2 and p-type second semiconductor layer 5. Hence, the photoelectric conversion efficiency can be improved.

Note that each of i-type amorphous semiconductor films 3i, 5i, n-type amorphous semiconductor film 3n, and p-type amorphous semiconductor film 5p preferably contains hydrogen to enhance the passivation performance.

N-side electrode 6, as a one-conductivity-type-side electrode, configured to collect electrons is formed on n-type amorphous semiconductor film 3n. On the other hand, p-side electrode 7, as the other-conductivity-type-side electrode, configured to collect holes is formed on p-type amorphous semiconductor film 5p. As illustrated in FIG. 2A, p-side electrode 7 and n-side electrode 6 are electrically insulated from each other by insulation regions D1 interposed therebetween.

As illustrated in FIG. 1, n-side electrode 6 includes n-side fingers 6B and n-side busbar 6A to which one end of each n-side finger 6B is connected. P-side electrode 7 includes p-side fingers 7B and p-side busbar 7A to which one end of each p-side finger 7B is connected. N-side fingers 6B of n-side electrode 6 and p-side fingers 7B of p-side electrode 7 interdigitate each other.

The material of each of n-side electrode 6 and p-side electrode 7 is not particularly limited as long as it is capable of collecting carriers. As illustrated in FIGS. 2A to 2C, in this embodiment, n-side electrode 6 and p-side electrode 7 are formed by a stacked body of first electrode layer 6a and second electrode layer 6b and a stacked body of first electrode layer 7a and second electrode layer 7b, respectively.

First electrode layers 6a, 7a can be made, for example, of a transparent conductive oxide (TCO) such as indium tin oxide (ITO) or the like. Specifically, in this embodiment, first electrode layers 6a, 7a is made of ITO. Note that first electrode layers 6a, 7a can be formed, for example, by a thin film formation method such as sputtering or chemical vapor deposition (CVD).

Second electrode layers 6b, 7b can be made, for example, of a metal such as Cu or an alloy. In this embodiment, second electrode layers 6b, 7b are made of Cu. Note that another electrode layer may be formed between first electrode layer 6a, 7a and second electrode layer 6b, 7b. Also, another electrode layer may be formed on second electrode layer 6b, 7b.

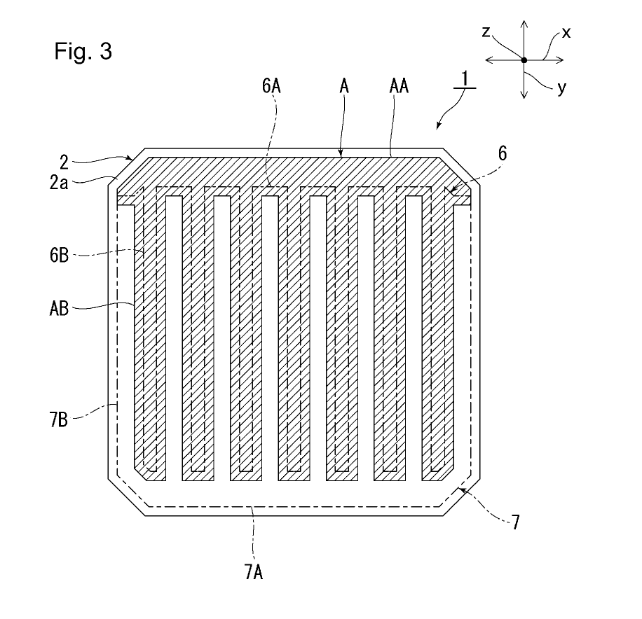

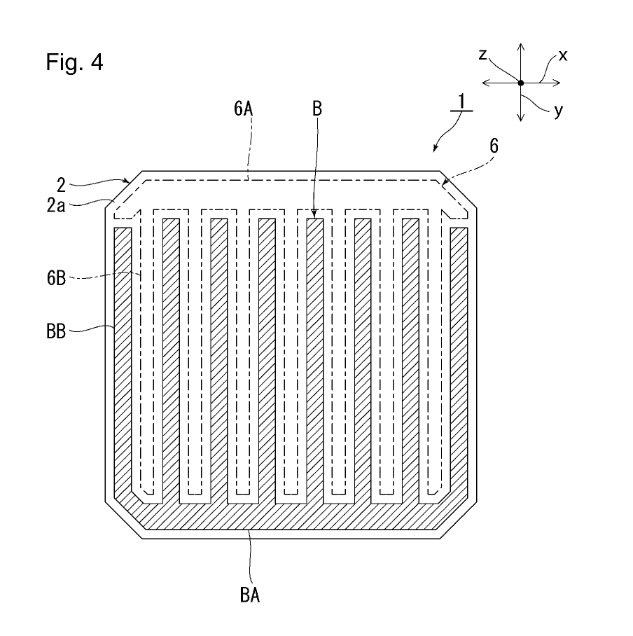

FIG. 3 is a view illustrating the arrangement of first region A in the first embodiment. FIG. 4 is a view illustrating the arrangement of second region B in the first embodiment.

In FIG. 3, first region A is illustrated with hatched lines. As illustrated in FIG. 3, first region A includes first finger sections AB which extend in a y direction, as a predetermined direction, and first busbar section AA to which one end of each first finger section AB is connected. First busbar section AA extends in the x direction which is a direction perpendicular to the y direction.

In FIG. 4, second region B is illustrated with hatched lines. As illustrated in FIG. 4, second region B includes second finger sections BB which extend in the y direction, and second busbar section BA to which one end of each second finger section BB is connected. Second busbar section BA extends in the x direction. As illustrated in FIGS. 3 and 4, first finger sections AB and second finger sections BB interdigitate each other.

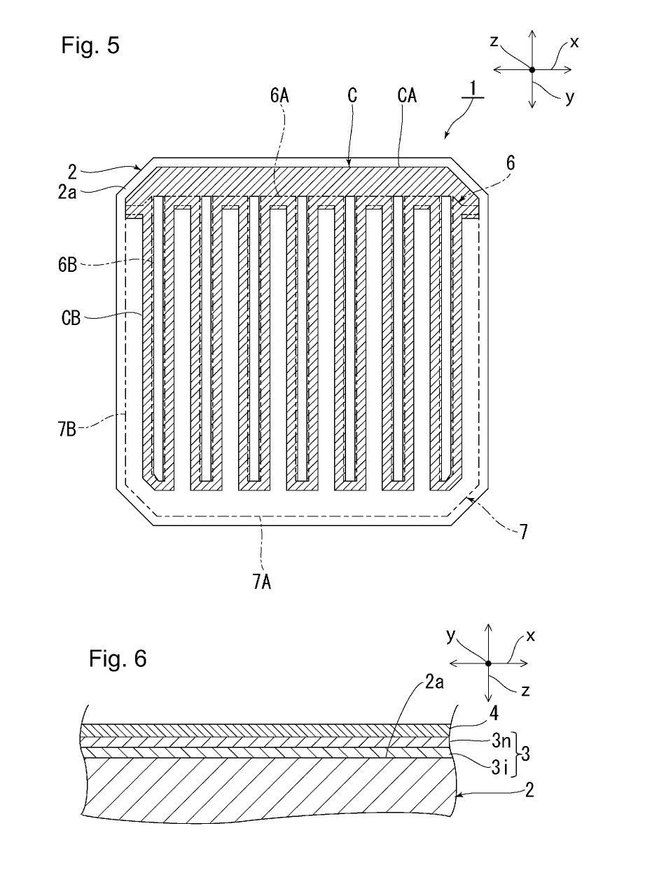

FIG. 5 is a view illustrating the arrangement of a third region in the first embodiment.

In FIG. 5, third region C is illustrated with hatched lines. As illustrated in FIG. 5, third region C includes third finger sections CB which extend in the y direction and third busbar section CA which extends in the x direction. Third finger sections CB are the areas in first finger sections AB where first semiconductor layer 3 and second semiconductor layer 5 overlap each other. Third busbar section CA is the area where first busbar section AA is situated. Thus, third region C is situated in the areas in first finger sections AB where first semiconductor layer 3 and second semiconductor layer 5 overlap each other, and is also situated in first busbar section AA. In other words, in this embodiment, insulation layer 4 is provided in first finger sections AB in the areas where first semiconductor layer 3 and second semiconductor layer 5 overlap each other, and is also provided in the area where first busbar section AA is situated. In other words, as shown in FIGS. 3 and 5, first busbar section AA is provided in third region C. More specifically, the substantially entire of first busbar section AA is provided in third region C. Also parts of first finger sections AB are provided in third region C. More specifically, the outline edge portion of each first finger section AB is provided in third region C, while the rest of each first finger section AB is provided in an area in the first area A other than the third area C.

As illustrated in FIGS. 2B and 2C, insulation layer 4 is provided in the area where first busbar section AA is situated. In the area where first busbar section AA is situated, insulation layer 4 is provided on first semiconductor layer 3, which is formed on main surface 2a of semiconductor substrate 2. On insulation layer 4, second semiconductor layer 5 is provided and n-side electrode 6 is formed thereon. Note that, in the area where first busbar section AA is situated, second semiconductor layer 5 does not necessarily have to be provided and n-side electrode 6 may be formed on insulation layer 4 without second semiconductor layer 5 provided thereon.

As illustrated in FIG. 2C, each p-side finger 7B of p-side electrode 7 and n-side busbar 6A of n-side electrode 6 are electrically insulated from each other by insulation region D2 interposed therebetween.

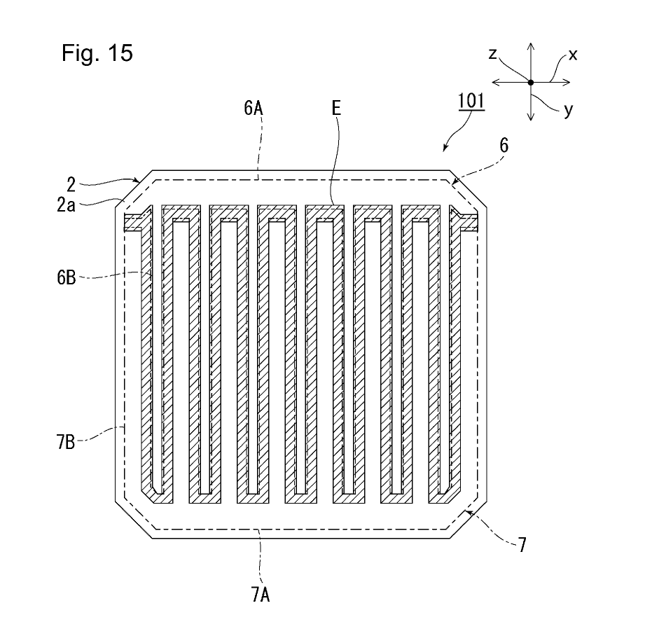

FIG. 15 is a view illustrating the arrangement of a third region in a solar cell of a comparison example. In FIG. 15, third region E is illustrated with hatched lines. As illustrated in FIG. 15, third region E in conventional solar cell 101 is formed only in sections corresponding to third finger sections CB in this embodiment, and third region E is not formed in a section corresponding to third busbar section CA in this embodiment. Thus, third region E is not formed in the area where first busbar section AA is situated, and insulation layer 4 is therefore not provided in the area where first busbar section

AA is situated. That is, as shown in FIGS. 15 and 3, first basbur section AA is not provided in third region E.

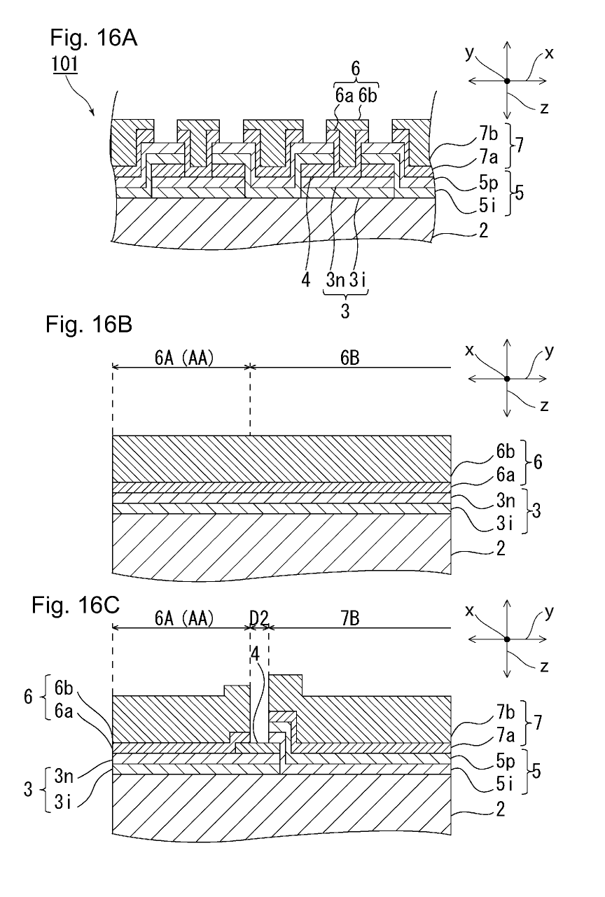

FIGS. 16A to 16C are schematic cross-sectional views of the solar cell structure of the comparison example, to be compared to FIGS. 2A to 2C illustrating this embodiment. As illustrated in FIG. 16B, no insulation layer is provided in the area where first busbar section AA is situated, and n-side electrode 6 is formed on first semiconductor layer 3 in the area of first busbar section AA. As illustrated in FIG. 16C, insulation layer 4 is provided only in and around insulation region D2 which is situated between each p-side finger 7B of p-side electrode 7 and n-side busbar 6A of n-side electrode 6.

In this embodiment, as illustrated in FIGS. 2A to 2C, insulation layer 4 is formed at a position that overlaps first busbar section AA in plan view. The short circuit current in solar cell 1 has been observed to increase when this structure is employed. Hence, the photoelectric conversion efficiency can be enhanced effectively.

In this embodiment, as described above, first semiconductor layer 3 as a semiconductor layer of the one conductivity type includes the stacked structure in which n-type amorphous semiconductor film 3n is formed on i-type amorphous semiconductor film 3i, and second semiconductor layer 5 as a semiconductor layer of the other conductivity type includes the stacked structured in which p-type amorphous semiconductor film 5p is formed on i-type amorphous semiconductor film 5i. However, the “semiconductor layer of the one conductivity type” and the “semiconductor layer of the other conductivity type” in the invention are not limited to these. For example, the semiconductor layer of the one conductivity type maybe formed only by n-type amorphous semiconductor film 3n as the first semiconductor film of the one conductivity type, and the semiconductor layer of the other conductivity type may be formed only by p-type amorphous semiconductor film 5p as the second semiconductor film of the other conductivity type. In other words, i-type amorphous semiconductor film 3i as the first intrinsic semiconductor film and i-type amorphous semiconductor film 5i as the second intrinsic semiconductor film do not necessarily have to be provided in the semiconductor layer of the one conductivity type and the semiconductor layer of the other conductivity type.

Method of Manufacturing Solar Cell

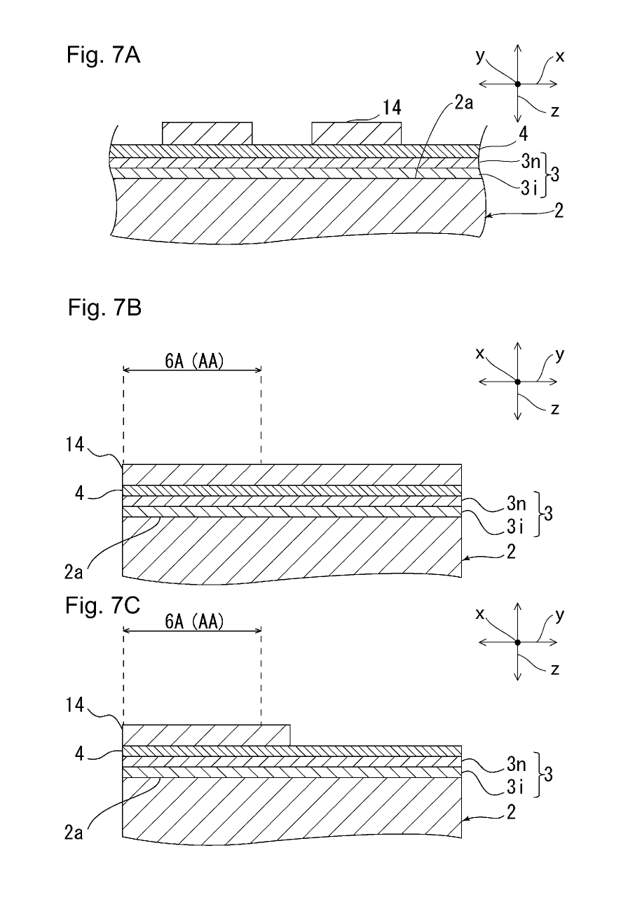

A method of manufacturing solar cell 1 in this embodiment is described below with reference to FIGS. 6 to 14C. Note that FIGS. 7A to 7C through FIGS. 14A to 14C are views each illustrating a manufacturing step; A is an enlarged schematic cross-sectional view illustrating apart of a cross section taken along line I-I illustrated in FIG. 1, B is a schematic cross-sectional view illustrating a cross section of a part taken along line II-II illustrated in FIG. 1, and C is a schematic cross-sectional view illustrating a cross section of a part taken along line illustrated in FIG. 1.

First, semiconductor substrate 2 is prepared. Then, as illustrated in FIG. 6, i-type amorphous semiconductor film 3i, n-type amorphous semiconductor film 3n, and insulation layer 4 are formed in this order on main surface 2a of semiconductor substrate 2. The method of forming each of i-type amorphous semiconductor film 3i, n-type amorphous semiconductor film 3n, and insulation layer 4 is not particularly limited. I-type amorphous semiconductor film 3i and n-type amorphous semiconductor film 3n can each be formed, for example, by chemical vapor deposition (CVD) such as plasma enhanced CVD or the like. Also, insulation layer 4 can be formed, for example, by a thin film formation method such as sputtering or CVD.

Then, as illustrated in FIGS. 7A to 7C, resist pattern 14 is formed on insulation layer 4 by photolithography. Resist pattern 14 is formed on a section other than the region where a p-type semiconductor layer is to be joined to semiconductor substrate 2 in a later step. In this step, resist pattern 14 is formed on the section where first busbar section AA and first finger sections AB mentioned above are to be situated.

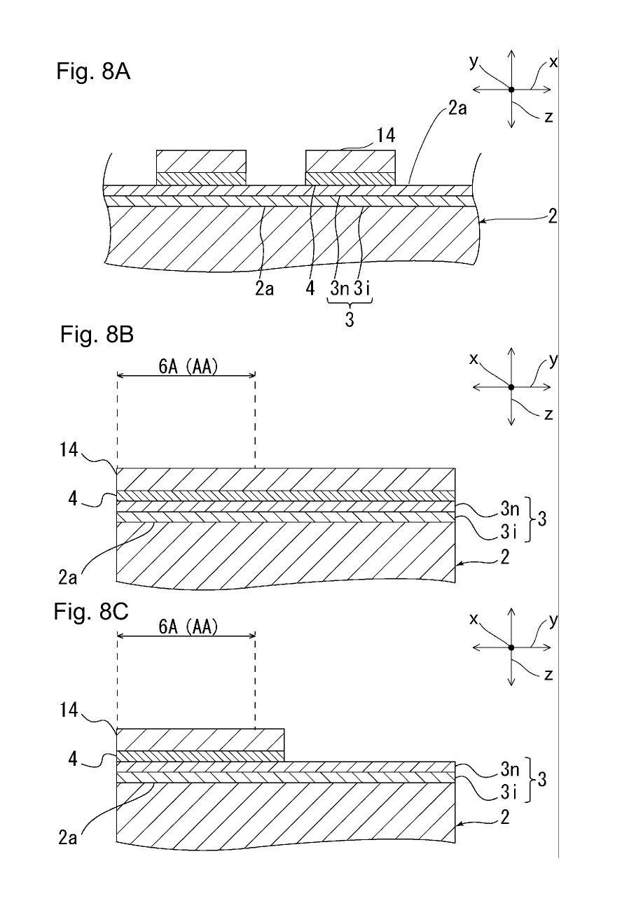

Then, as illustrated in FIGS. 8A to 8C, insulation layer 4 is etched with resist pattern 14 used as a mask, so that the section of insulation layer 4 other than the section thereof covered with resist pattern 14 is removed. Since resist pattern 14 is formed in first busbar section AA and first finger sections AB, insulation layer 4 in the section where first busbar section AA and first finger sections AB are situated is not removed. Note that insulation layer 4 can be etched using, for example, an acidic etchant such as HF aqueous solution in the case where insulation layer 4 is made of silicon nitride, silicon oxide, or silicon oxynitride.

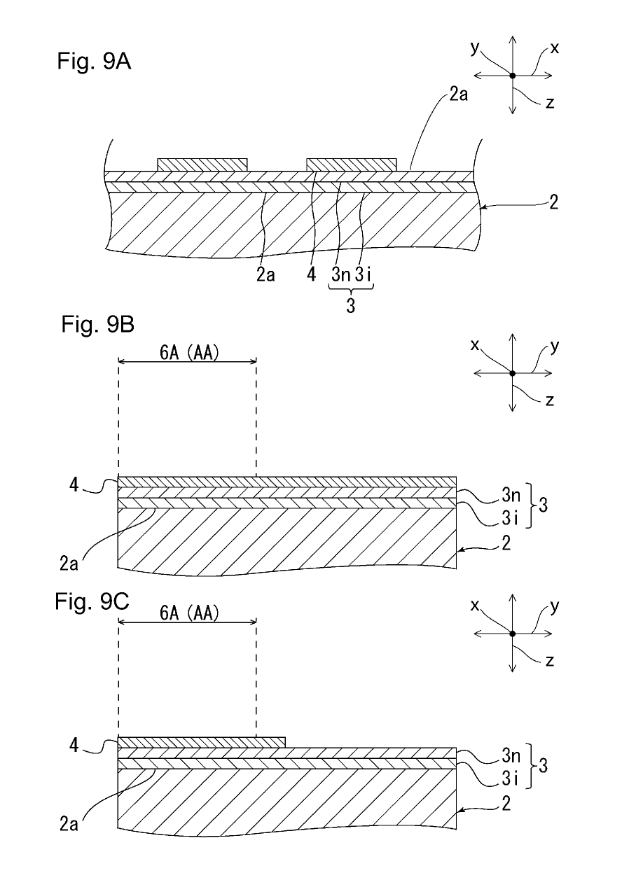

Then, as illustrated in FIGS. 9A to 9C, resist pattern 14 is detached. Note that the resist pattern can be detached using, for example, tetramethylammonium hydroxide (TMAH) or the like.

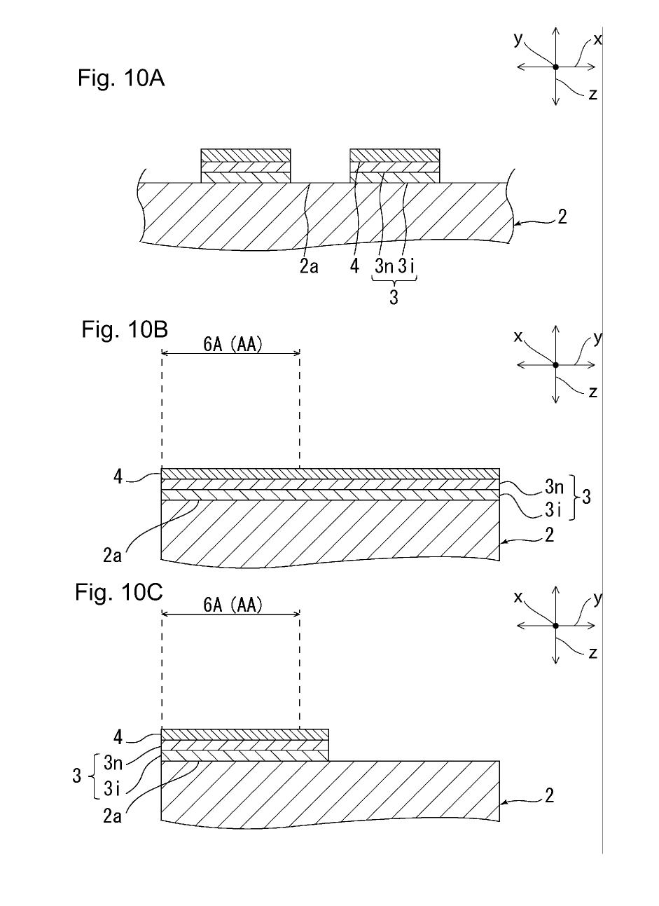

Then, as illustrated in FIGS. 10A to 10C, i-type amorphous semiconductor film 3i and n-type amorphous semiconductor film 3n are etched using alkaline etchant, so that the sections of i-type amorphous semiconductor film 3i and n-type amorphous semiconductor film 3n which are not covered with insulation layer 4 are removed. As a result, with i-type amorphous semiconductor film 3i and n-type amorphous semiconductor film 3n, first semiconductor layer 3 including i-type amorphous semiconductor film 3i and n-type amorphous semiconductor film 3n is formed.

Here, as mentioned above, in this embodiment, insulation layer 4 is made of silicon nitride. For this reason, the rate of etching of insulation layer 4 is high with acidic etchant but is low with alkaline etchant. In contrast, i-type amorphous semiconductor film 3i and n-type amorphous semiconductor film 3n are each made of amorphous silicon. For this reason, the rate of etching of each of i-type amorphous semiconductor film 3i and n-type amorphous semiconductor film 3n is low with acidic etchant but is high with alkaline etchant.

Thus, the acidic etchant used in the step illustrated in FIGS. 8A to 8C etches insulation layer 4 but does substantially not etch i-type amorphous semiconductor film 3i and n-type amorphous semiconductor film 3n. On the other hand, the alkaline etchant used in the step illustrated in FIGS. 10A to 10C etches i-type amorphous semiconductor film 3i and n-type amorphous semiconductor film 3n but does substantially not etch insulation layer 4. Hence, in the step illustrated in FIGS. 8A to 8C and the step illustrated in FIGS. 10A to 10C, insulation layer 4, i-type amorphous semiconductor film 3i, and n-type amorphous semiconductor film 3n can be selectively etched.

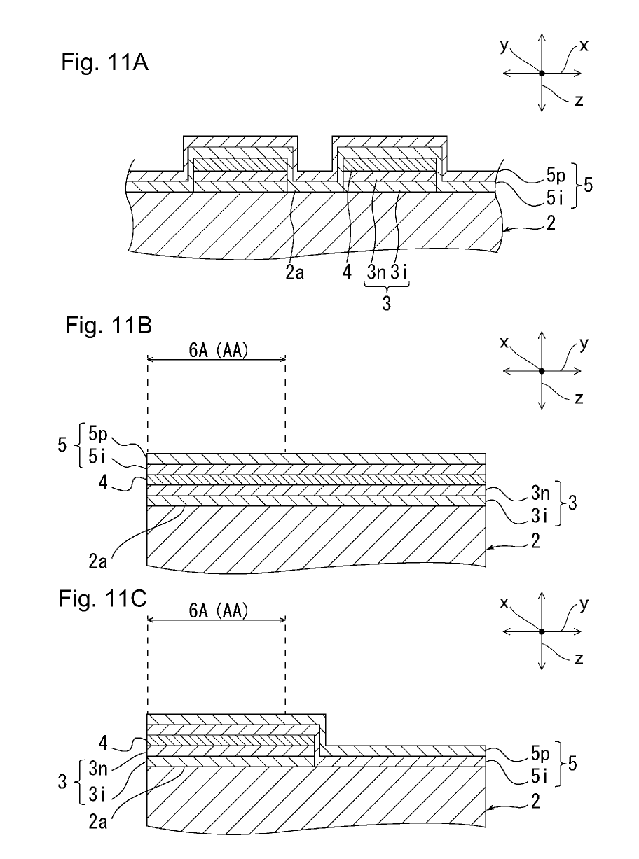

Then, as illustrated in FIGS. 11A to 11C, i-type amorphous semiconductor film 5i and p-type amorphous semiconductor film 5p are sequentially formed in this order on main surface 2a of semiconductor substrate 2 and insulation layer 4. The method of forming each of i-type amorphous semiconductor film 5i and p-type amorphous semiconductor film 5p is not particularly limited. For example, they may be formed by CVD or the like.

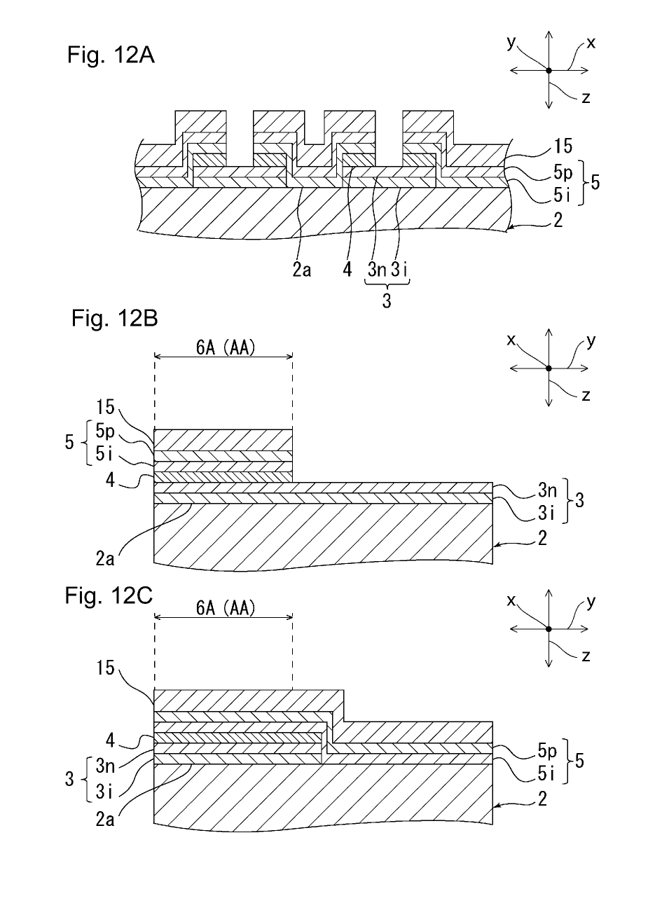

Then, as illustrated in FIGS. 12A to 12C, resist pattern 15 is formed, followed by etching sections of i-type amorphous semiconductor film 5i and p-type amorphous semiconductor film 5p illustrated in FIGS. 11A to 11C that are situated on center sections of insulation layer 4. First, the sections of i-type amorphous semiconductor film 5i and p-type amorphous semiconductor film 5p in the areas of n-side fingers 6B are etched using a hydrofluoric acid-based etchant such as hydrofluoric acid-nitric acid. As a result, second semiconductor layer 5 including i-type amorphous semiconductor film 5i and p-type amorphous semiconductor film 5p illustrated in FIGS. 12A to 12C is formed. Then, insulation layer 4 is etched using acidic etchant similar to that used in the step illustrated in FIGS. 8A to 8C, so that the section of first semiconductor layer 3 not overlapping second semiconductor layer 5 in plan view is exposed.

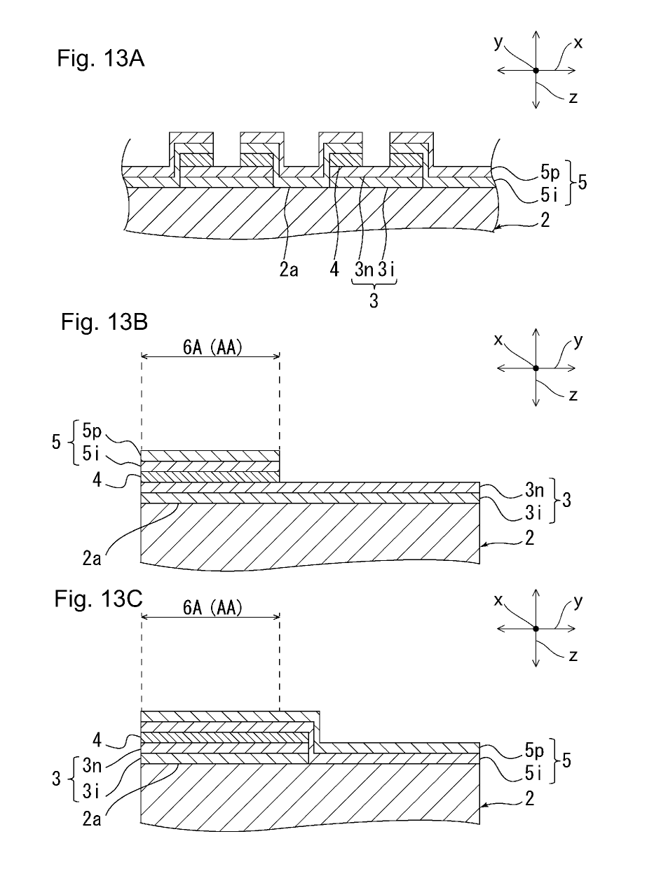

Then, as illustrated in FIGS. 13A to 13C, resist pattern 15 illustrated in FIGS. 12A to 12C is detached. Resist pattern 15 is detached by a method similar to that in the step illustrated in FIGS. 9A to 9C.

Through the above steps, insulation layer 4 can be formed at a position including first busbar section AA, and n-type first semiconductor layer 3 and p-type second semiconductor layer 5 can be formed on main surface 2a of semiconductor substrate 2.

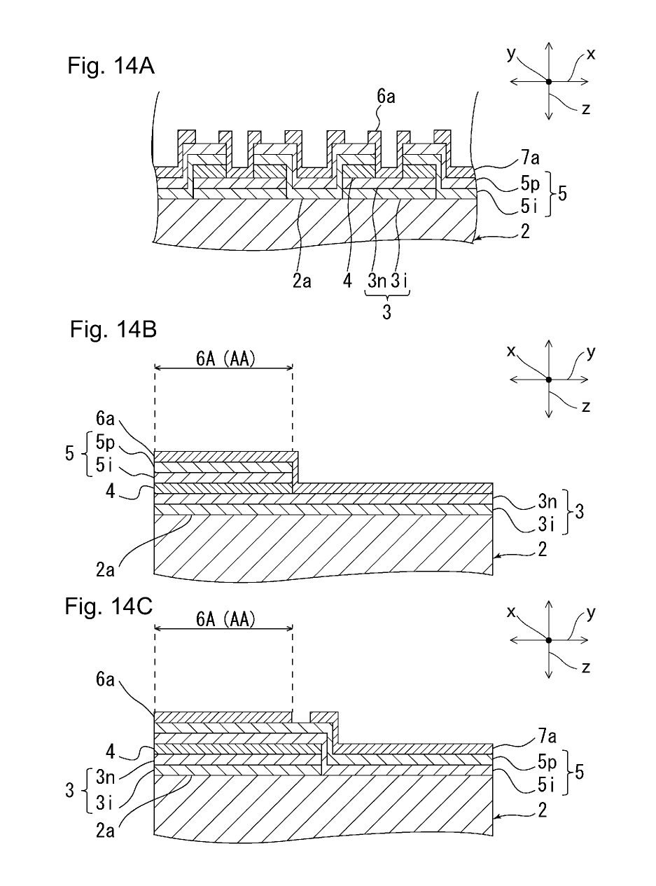

Then, as illustrated in FIGS. 14A to 14C, first electrode layers 6a, 7a are formed. In this step, first electrode layer 6a and first electrode layer 7a can be formed by firstly forming a first electrode layer on first semiconductor layer 3 and on second semiconductor layer 5 by a thin film formation method such as CVD, for example, plasma enhanced CVD, or sputtering, and then patterning the first electrode layer by photolithography.

Then, second electrode layer 6b and second electrode layer 7b illustrated in FIGS. 2A to 2C are formed on first electrode layer 6a and first electrode layer 7a, respectively, by electroplating or the like.

Through the above steps, solar cell 1 illustrated in FIGS. 2A to 2C can be manufactured.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

What is claimed is:

1. A solar cell, comprising:
a semiconductor substrate of one conductivity type including a main surface;
a first semiconductor layer of the one conductivity type formed on the main surface of the semiconductor substrate;
a second semiconductor layer of the other conductivity type formed on the main surface of the semiconductor substrate; and
an insulation layer provided between the first semiconductor layer and the second semiconductor layer in an area where the first semiconductor layer and the second semiconductor layer overlap each other, wherein
the solar cell includes
a first region where the first semiconductor layer is joined to the semiconductor substrate,
a second region where the second semiconductor layer is joined to the semiconductor substrate, and
a third region, which is apart of the first region, where the insulation layer is provided,
the first region includes first finger sections which extend in a direction and a first busbar section to which one end of each of the first finger sections is connected,
the second region includes second finger sections which extend in the direction and a second busbar section to which one end of each of the second finger sections is connected,
the first finger sections and the second finger sections interdigitate each other, and
at least a part of the first busbar section is provided in the third region.

2. The solar cell according to claim 1, wherein the one conductivity type is n type and the other conductivity type is p type.

3. The solar cell according to claim 1, wherein
the first semiconductor layer includes a multi-layer structure including a first intrinsic semiconductor film formed on the main surface of the semiconductor substrate, and a first semiconductor film of the one conductivity type formed on the first intrinsic semiconductor film, and
the second semiconductor layer includes a multi-layer structure including a second intrinsic semiconductor film formed on the main surface of the semiconductor substrate, and a second semiconductor film of the other conductivity type formed on the second intrinsic semiconductor film.

4. The solar cell according to claim 1, wherein
the first semiconductor layer and the second semiconductor layer contain amorphous silicon, and
the insulation layer contains silicon nitride.

5. The solar cell according to claim 1, wherein
the entire of the first busbar section is substantially provided in the third region.

6. The solar cell according to claim 1, wherein
a part of the first finger section is provided in the third region.

7. The solar cell according to claim 1, wherein
the outline edge portions of the first finger sections are provided in the third area.

8. The solar cell according to claim 1, wherein
the outline edge portions of the first finger sections are provided in the third area, while the rest of the first finger sections is provided in an area in the first area other than the third area.

9. A solar cell, comprising:
a semiconductor substrate of one conductivity type including a main surface;
a first semiconductor layer of the one conductivity type formed on the main surface of the semiconductor substrate;
an insulation layer provided on a part of the first semiconductor layer;
a second semiconductor layer of the other conductivity type formed on the main surface of the semiconductor substrate and the insulation layer, wherein
the solar cell includes
a first region where the first semiconductor layer is joined to the semiconductor substrate,
a second region where the second semiconductor layer is joined to the semiconductor substrate, and
a third region, which is a part of the first region, where the insulation layer is provided,
the first region includes first finger sections which extend in a direction and a first busbar section to which one end of each of the first finger sections is connected,
the second region includes second finger sections which extend in the direction and a second busbar section to which one end of each of the second finger sections is connected,
the first finger sections and the second finger sections interdigitate each other, and
at least a part of the first busbar section is provided in the third region.

10. The solar cell according to claim 9, wherein
the entire of the first busbar section is substantially provided in the third region.
